(19) United States
(12) Patent Application Publication
(10) Pub. No.: US 2004/0196881 A1
(43) Pub. Date: Oct. 7, 2004

(54) Semiconductor laser and lasing operation

(75) Inventor: Tomoaki Toda, Sagamihara City (JP)

Correspondence Address: OLIFF & BERRIDGE, PLC, P.O. BOX 19928, ALEXANDRIA, VA, 22320, US

(73) Assignee: Japan Aerospace Exploration Agency, Chofu City (JP)

(21) Appl. No.: 10/810,729

(22) Filed: Mar. 29, 2004

(30) Foreign Application Priority Data
Apr. 4, 2003 (JP) 2003-101367

(51) Int. Cl. H01S 5/00

(52) U.S. Cl. 372/43

(57) ABSTRACT

A semiconductor laser includes a semiconductor layer group composed of an n-type emitter layer, a p-type base layer, an active layer, an n-type base layer and a p-type emitter layer which are successively formed on a given substrate. Then, the semiconductor layer group includes three pn junctions. The first pn junction is formed of the n-type emitter layer and the p-type base layer, and the second pn junction is formed of the p-type base layer and the n-type base layer, and the third pn junction is formed of the n-type base layer and the p-type emitter layer.

### BACKGROUND OF THE INVENTION

1. Field of the Invention

This invention relates to a semiconductor laser and lasing operation.

2. Description of the Related Art

Researches for semiconductor lasers tends to attain full growth, so that as of now, attention of semiconductor laser industrial field is paid to shorter wavelength oscillation of semiconductor laser and integration of a semiconductor laser with another element. In view of industrial use of semiconductor laser, however, the semiconductor laser has not yet been completed.

A conventional semiconductor laser is composed of a semiconductor layer group which constitutes a pn junction so as to sandwich an active layer on a substrate. In this case, by applying a given voltage to the semiconductor laser in the forward direction of the pn junction, a given current is injected to the active layer, originated from the forward voltage, to be excited through the carrier diffusion on the condition canceling diffusion voltage and thus, internal electric field of junction and thus, non-electric field, so that the semiconductor laser is oscillated. In other words, the conventional semiconductor laser can be oscillated only by the application of forward voltage for the pn junction thereof. As of now, therefore, various oscillations for the semiconductor laser can not be established.

In this point of view, although a quantum cascade laser has been developed, it is still under development for a practical use due to the oscillation wavelength and so on (see, “High power mid-infrared (λ˜5 μm) quantum cascade lasers operating above room temperature”, Appl. Phys. Lett. 68(26), 24 Jun. 1996).

### SUMMARY OF THE INVENTION

It is an object of the present invention to provide a new semi-conductor laser which can realize various oscillations of laser and a lasing operation.

For achieving the above object, this invention relates to a semiconductor laser comprising a semiconductor layer group, wherein the semiconductor layer group is composed of an n-type emitter layer, a p-type base layer, an active layer, an n-type base layer and a p-type emitter layer which are successively formed on a given substrate.

In the semiconductor laser of the present invention, as mentioned above, the five-layered semiconductor layer group is provided, which is composed of the n-type emitter layer, the p-type base layer, the active layer, the n-type base layer and the p-type emitter layer. In this case, in the semiconductor layer group, three pn junctions are formed. The first pn junction is formed of the n-type emitter layer and the p-type base layer, and the second pn junction is formed of the p-type base layer and the n-type base layer, and the third pn junction is formed of the n-type base layer and the p-type emitter layer. Since the second pn junction includes the active layer at the midpoint thereof, the second pn junction constitute a so-called conventional pn junction type semiconductor laser.

The semiconductor layer group can be classified into the first semiconductor layer group and the second semiconductor layer group: The first semiconductor layer group is composed of the n-type emitter layer, the p-type base layer, the active layer, and the n-type base layer which are formed successively on the substrate, and the second semiconductor layer group is composed of the p-type base layer, the active layer, the n-type layer, and the p-type emitter layer. Therefore, the first semiconductor layer group constitutes a so-called npn-type bipolar transistor, and the second semiconductor layer group constitutes a so-called pnp-type bipolar transistor.

As a result, the semiconductor layer group is composed independently of the pn junction-type semiconductor laser, the npn-type bipolar transistor, and the pnp-type bipolar transistor. Therefore, when the semiconductor laser and the bipolar transistors are controlled independently, the semiconductor laser of the present invention can be oscillated in various operations.

Since the conventional semiconductor laser is composed only of the pn-type semiconductor laser, the applying direction of voltage (voltage on the current flow, that is, positive voltage or negative voltage) for the semiconductor laser determines the transporting direction of electrons and holes. Concretely, by applying a forward voltage for the pn junction of the semiconductor laser, a current (diffusion current) is injected into the active layer to be excited so that the semiconductor is lased to generate a certain wavelength of light. Microscopically, the current injection is realized because the electrons and holes are flowed in the direction parallel to the forward voltage. Therefore, in the conventional semiconductor laser, the applying direction of voltage depends one-on-one on the transporting direction of the electrons and the holes.

In the semiconductor laser of the present invention, in contrast, since the pn junction semiconductor laser and the bipolar transistors made of the first semiconductor layer group and the second semiconductor layer group are incorporated, if the semiconductor laser and the bipolar transistors are controlled independently, the excitation of the active layer and the light generation of a given wavelength through the current injection and the transportations of the electrons and the holes by the first and the second semiconductor layer groups can be performed independently.

Concretely, when a forward voltage is applied to the pn junction semiconductor laser, the active layer is excited by the diffusion current from the forward voltage to generate and oscillate a light of a given wavelength. Moreover, when a smaller forward voltage than the inherent barrier voltage (diffusion voltage) of the pn junction semiconductor laser is applied to through the pn junction semiconductor laser, a drift current is generated in the semiconductor laser in addition to the diffusion current. In this case, the active layer is excited by the drift current in addition to the diffusion current to generate and oscillate a light of a given wavelength. In addition, when a relatively large backward voltage is applied to the pn junction semiconductor laser, a given drift current is generated in the pn junction semiconductor laser in substitution for the diffusion current. In this case, the active layer is excited by the drift current to generate and oscillate a light of a given wavelength.

In this way, the semiconductor laser of the present invention can be oscillated by the forward voltage or the backward voltage, so that according to the semiconductor laser of the present invention, various lasing operations can be realized.

If the first semiconductor layer group and the second semiconductor layer group are controlled appropriately, the electrons and the holes can be flowed in a given direction through the semiconductor active layer. Therefore, a given current can be flowed through the semiconductor laser active layer. If the drift current is too small to excite the active layer, electrons and holes can be supplied from the first semiconductor layer group and the second semiconductor layer group, respectively, so that the active layer is excited enough to achieve lasing and generate light of a certain wavelength.

If the first semiconductor layer group and the second semiconductor layer group are controlled appropriately to adjust the amount of the electrons and the holes to be injected into the active layer, the excitation in the active layer can be controlled. In this case, the intensity modulation of light from the semiconductor laser can be realized.

In a preferred embodiment of the present invention, an electron traveling layer is formed between the p-type base layer and the active layer of the first semiconductor layer group. In this case, a current oscillation due to Gunn effect of the semiconductor layer group achieves a high-speed modulation of light intensity due to the relaxation oscillation of the semiconductor laser, so that the intensity of the light generated and oscillated can be modulated at high speed.

Details and other features and advantages of the present invention will be described below.

### BRIEF DESCRIPTION OF THE DRAWINGS

For better understanding of the present invention, reference is made to the attached drawings, wherein

FIG. 1 is a structural view illustrating a semiconductor laser according to the present invention,

FIG. 2 is a schematic view illustrating the junction of the semi-conductor layer groups of the semiconductor layer illustrated in FIG. 1, and

FIG. 3 is a structural view illustrating another semiconductor laser modified from the semiconductor laser illustrated in FIG. 1.

### DESCRIPTION OF THE PREFERRED EMBODIMENTS

This invention will be described in detail hereinafter.

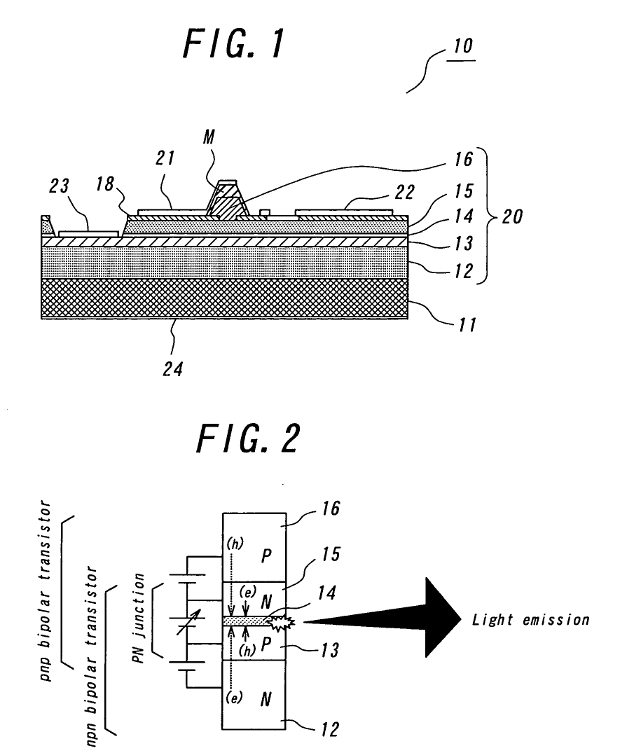

FIG. 1 is a structural view illustrating a semiconductor laser according to the present invention, and FIG. 2 is a schematic view illustrating the junction of the semiconductor layer groups of the semiconductor layer illustrated in FIG. 1.

In a semiconductor laser 10 illustrated in FIG. 1, on a substrate 11 are successively formed an n-type emitter layer 12, a p-type base layer 13, an active layer 14, an n-type base layer 15 and a p-type emitter layer 16. The p-type emitter layer 16 is formed in mesa-stripe shape. The n-type emitter layer 12, the p-type base layer 13, the active layer 14, the n-type base layer 15 and the p-type emitter layer 16 constitute a semiconductor layer group 20 to function as a semiconductor laser.

On the p-type emitter layer 16 is formed an electrode layer 21 via a cap layer 17, and on the n-type base layer 15 is formed an electrode layer 22 via an insulating layer 18. On the partially exposed surface of the p-type base layer 13 is formed an electrode layer 23, and on the rear surface of the substrate 11 is formed an electrode layer 24.

The semiconductor layer group 20 is composed of the five layers of the n-type emitter layer 12 through the p-type emitter layer 16 to constitute a five-layered structure. Then, the semiconductor layer group 20 includes three pn junctions: The first pn junction is formed of the n-type emitter layer 12 and the p-type base layer 13, and the second pn junction is formed of the p-type base layer 13 and the n-type base layer 15, and the third pn junction is formed of the n-type base layer 15 and the p-type emitter layer 16.

In the semiconductor layer group 20, the p-type base layer 13, the active layer 14 and the n-type base layer 15 constitute a pn junction type semiconductor laser. The n-type emitter layer 12, the p-type base layer 13, the active layer 14 and the n-type base layer 15 constitute a first semiconductor layer group functioning as an npn-type bipolar transistor. The p-type base layer 13, the active layer 14, the n-type base layer 15 and the p-type emitter layer 16 constitute a second semiconductor layer group functioning as a pnp-type bipolar transistor.

As a result, the semiconductor laser 10 is composed independently of the pn junction-type semiconductor laser, the npn-type bipolar transistor, and the pnp-type bipolar transistor. Therefore, if the semiconductor laser and the bipolar transistors are controlled independently, the semiconductor laser of the present invention can realize various oscillations.

Concretely, when a forward voltage is applied to the pn junction semiconductor laser, the active layer 14 is excited by the diffusion current originated from the forward voltage to generate and oscillate a light of a given wavelength. Moreover, when a smaller forward voltage than the inherent barrier voltage (diffusion voltage) of the pn junction semiconductor laser is applied to the pn junction semiconductor laser in addition to the above-mentioned forward voltage, a drift current is generated in the semiconductor laser 10 in addition to the diffusion current. In this case, the active layer 14 is excited by the drift current in addition to the diffusion current from the forward voltage to achieve lasing at a certain wavelength of light. In addition, when a relatively large backward voltage is applied to the pn junction semiconductor laser, a given drift current is generated in the pn junction semiconductor laser in substitution for the diffusion current. In this case, the active layer 14 is excited by the drift current only to generate and oscillate a light of a given wavelength.

In this way, the semiconductor laser 10 illustrated in FIG. 1 can be oscillated by the forward voltage or the backward voltage, so that according to the semiconductor laser of the present invention, various lasing operations can be realized.

If the first semiconductor layer group functioning as the npn-type bipolar transistor and the second semiconductor layer group functioning as the pnp-type bipolar transistor are controlled appropriately, the electrons and the holes can be flowed in a given direction through the semiconductor laser 10. Therefore, a given current can be flowed through the semiconductor laser 10.

If the drift current is too small to excite the active layer, electrons and holes can be supplied from the first semiconductor layer group and the second semiconductor layer group, respectively, so that the active layer is excited enough to achieve lasing and generate light of a certain wavelength.

If the first semiconductor layer group and the second semiconductor layer group are controlled appropriately to adjust the amount of the electrons and the holes to be injected into the active layer 14, the excitation in the active layer 14 can be controlled. In this case, the intensity modulation of light from the semiconductor laser 10 can be realized.

Since a conventional semiconductor laser is composed only of a pn junction-type semiconductor laser, the applying direction of voltage for the semiconductor layer determines the transporting direction of electrons and holes.

The n-type emitter layer 12 through the p-type emitter layer 16 of the semiconductor layer group 20 may be made of III-V group semiconductor com-pounds, for example, which can be defined as In_{1-X}GaₓAs_{1-Y}P_{Y} (0≦X≦1, 0≦Y≦1).

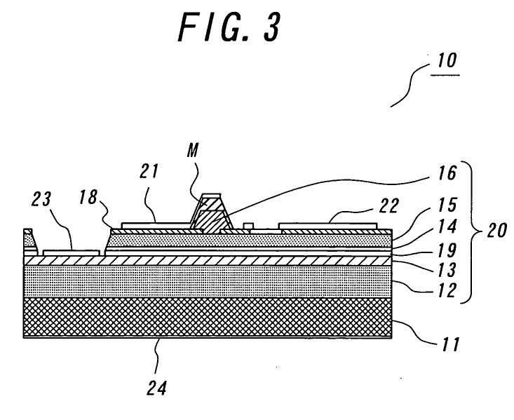

FIG. 3 is a structural view illustrating another semiconductor laser modified from the semiconductor laser illustrated in FIG. 1. For simplicity, like reference numerals are imparted to corresponding or like components throughout FIGS. 1-3. In the semiconductor element 10 illustrated in FIG. 3, an electron traveling layer 19 is provided between the active layer 14 and the p-type base layer 13 of the semiconductor layer group 20. Therefore, a current oscillation due to Gunn effect of the semiconductor layer group 20 achieves a high-speed modulation of light intensity due to the relaxation oscillation of the semi-conductor laser 10, so that the intensity of the light generated can be modulated at high speed.

Other components of the semiconductor laser 10 illustrated in FIG. 3 are constructed in the same manner as the ones illustrated in FIG. 1.

The electron traveling layer 19 may be made of a III-V group semiconductor compound, for example, which can be defined as In_{1-P}Ga_{P}As_{1-Q}P_{Q} (0≦P≦1, 0≦Q≦1), as the n-type emitter layer 12 and the like.

Although the present invention was described in detail with reference to the above examples, this invention is not limited to the above disclosure and every kind of variation and modification may be made without departing from the scope of the present invention.

For example, in the above-mentioned embodiment, on the substrate 11 are successively formed the n-type emitter layer 12, the p-type base layer 13, the active layer 14, the n-type base layer 15 and the p-type emitter layer 16, but the stacking order of semiconductor layer can be inversed. In other words, in the present invention, it is required that the semiconductor layers are formed so as to be successively adjacent to one another, but the stacking order of semiconductor layer is not required.

As mentioned above, according to the present invention can be provided a new semiconductor laser which can realize various oscillations of laser and a lasing operation.

What is claimed is:

1. A semiconductor laser comprising a semiconductor layer group, wherein said semiconductor layer group is composed of an n-type emitter layer, a p-type base layer, an active layer, an n-type base layer and a p-type emitter layer which are successively formed on a given substrate.

2. The semiconductor laser as defined in claim 1, wherein a voltage is applied to said active layer to generate a drift current therein and said active layer is excited by said drift current to generate and oscillate a light of a given wavelength.

3. The semiconductor laser as defined in claim 2, a backward voltage is applied to a pn junction composed of said p-type base layer, said active layer and said n-type base layer.

4. The semiconductor laser as defined in claim 1, wherein a voltage is applied to said active layer to generate a diffusion current therein and said active layer is excited by said diffusion current to generate and oscillate a light of a given wavelength.

5. The semiconductor laser as defined in claim 4, a forward voltage is applied to a pn junction composed of said p-type base layer, said active layer and said n-type base layer.

6. The semiconductor laser as defined in claim 1, wherein a voltage is applied to said active layer to generate a diffusion current and a drift current therein and said active layer is excited by said diffusion current and said drift current to generate and oscillate a light of a given wavelength.

7. The semiconductor laser as defined in claim 6, two kinds of forward voltages are applied to a pn junction composed of said p-type base layer, said active layer and said n-type base layer.

8. The semiconductor laser as defined in claim 1, wherein said n-type emitter layer, said p-type base layer, said active layer and said n-type base layer, which are successively formed, constitute a first semiconductor layer group functioning a bipolar transistor, and by driving said first semiconductor layer group, an amount of electrons to be injected into said active layer is controlled.

9. The semiconductor laser as defined in claim 8, wherein said p-type base layer, said active layer, said n-type base layer and said p-type emitter layer, which are successively formed, constitute a second semiconductor layer group functioning a bipolar transistor, and by driving said second semiconductor layer group, an amount of holes to be injected into said active layer is controlled.

10. The semiconductor laser as defined in claim 9, wherein by controlling at least one of said amount of electrons and said amount of holes to be injected into said active layer, an intensity of said light generated and oscillated is modulated.

11. The semiconductor laser as defined in claim 1, wherein said semiconductor layer group is made of III-V group semiconductor compound.

12. The semiconductor laser as defined in claim 11, wherein said III-V group semiconductor compound is defined as In_{1-X}GaₓAs_{1-Y}P_{Y} (0≦X≦1, 0≦Y≦1).

13. The semiconductor laser as defined in claim 1, wherein said semiconductor layer group includes an electron traveling layer between said p-type base layer and said active layer.

14. The semiconductor laser as defined in claim 13, wherein said electron traveling layer is made of III-V group semiconductor compound.

15. The semiconductor laser as defined in claim 14, wherein said III-V group semiconductor compound is defined as In_{1-P}GaPAs_{1-Q}P_{Q} (0≦P≦1, 0≦Q≦1).

16. A method for oscillating a semiconductor laser comprising a semiconductor layer group composed of an n-type emitter layer, a p-type base layer, an active layer, an n-type base layer and a p-type emitter layer which are successively formed on a given substrate, comprising a step of:
applying a voltage to said active layer to generate a drift current therein so that said active layer is excited by said drift current to generate and oscillate a light of a given wavelength.

17. The oscillating method as defined in claim 16, wherein a backward voltage is applied to a pn junction composed of said p-type base layer, said active layer and said n-type base layer.

18. A method for oscillating a semiconductor laser comprising a semiconductor layer group composed of an n-type emitter layer, a p-type base layer, an active layer, an n-type base layer and a p-type emitter layer which are successively formed on a given substrate, comprising a step of:
applying a voltage to said active layer to generate a diffusion current therein so that said active layer is excited by said diffusion current to generate and oscillate a light of a given wavelength.

19. The oscillating method as defined in claim 18, wherein a forward voltage is applied to a pn junction composed of said p-type base layer, said active layer and said n-type base layer.

20. A method for oscillating a semiconductor laser comprising a semiconductor layer group composed of an n-type emitter layer, a p-type base layer, an active layer, an n-type base layer and a p-type emitter layer which are successively formed on a given substrate, comprising a step of:
applying a voltage to said active layer to generate a diffusion current and a drift current therein so that said active layer is excited by said diffusion current and said drift current to generate and oscillate a light of a given wavelength.

21. The oscillating method as defined in claim 20, wherein two kinds of forward voltages are applied to a pn junction composed of said p-type base layer, said active layer and said n-type base layer.

22. The oscillating method as defined in claim 16, wherein said n-type emitter layer, said p-type base layer, said active layer and said n-type base layer, which are successively formed, constitute a first semiconductor layer group functioning a bipolar transistor, and by driving said first semiconductor layer group, an amount of electrons to be injected into said active layer is controlled.

23. The oscillating method as defined in claim 22, wherein said p-type base layer, said active layer, said n-type base layer and said p-type emitter layer, which are successively formed, constitute a second semiconductor layer group functioning a bipolar transistor, and by driving said second semiconductor layer group, an amount of holes to be injected into said active layer is controlled.

24. The oscillating method as defined in claim 16, wherein said semiconductor layer group includes an electron traveling layer between said p-type base layer and said active layer, whereby a current oscillation due to Gunn effect of said semiconductor layer group achieves a high-speed modulation of light intensity due to a relaxation oscillation of said semiconductor laser so that an intensity of said light generated and oscillated can be modulated at high speed.
